(19) United States
(12) Patent Application Publication
(10) Pub. No.: US 2024/0191357 A1
(43) Pub. Date: Jun. 13, 2024

(54) SHOWER HEAD ASSEMBLY AND FILM FORMING APPARATUS

(71) Applicant: TOKYO ELECTRON LIMITED, Tokyo (JP)

(72) Inventors: Yuta SORITA, Nirasaki City (JP); Takashi KAKEGAWA, Nirasaki City (JP); Hiroo KAWASAKI, Nirasaki City (JP)

(21) Appl. No.: 18/534,880

(22) Filed: Dec. 11, 2023

(30) Foreign Application Priority Data
Dec. 12, 2022 (JP) 2022-198125

(51) Int. Cl. C23C 16/455; C23C 16/16; C23C 16/56

(52) U.S. Cl. CPC C23C 16/45565; C23C 16/16; C23C 16/45574; C23C 16/56

(57) ABSTRACT

A shower head assembly, which is disposed in a film forming apparatus that alternately repeats film formation and etching to form a metal film in a recess formed in a substrate, includes: a first plate having arc-shaped first slits formed in the first plate; and a second plate having arc-shaped second slits formed in the second plate, wherein the second plate is disposed below the first plate to vertically overlap with the first plate, and the second slits are formed at locations such that the second slits do not overlap with the first slits in a plan view.

### CROSS-REFERENCE TO RELATED APPLICATION

This application is based upon and claims the benefit of priority from Japanese Patent Application No. 2022-198125, filed on Dec. 12, 2022, the entire contents of which are incorporated herein by reference.

### TECHNICAL FIELD

The present disclosure relates to a shower head assembly and a film forming apparatus.

### BACKGROUND

For example, Patent Document 1 provides a nozzle device for surface treatment, which is capable of spraying a processing gas onto a surface of a workpiece with a uniform concentration. In Patent Document 1, a gas passage of the nozzle device includes a gas supply port through which the processing gas is supplied, a passage branch that divides the processing gas from the gas supply port and directs it to multiple downstream ends of branches arranged horizontally at intervals on a straight line, a merger that linearly and continuously extends in parallel with the arrangement direction of the downstream ends of the branches, a flow direction changer, and a blowout slit. The flow direction changer includes a first passage portion that directs downward the processing gas, which is sent from the multiple downstream ends of the branches, to the merger, a second passage portion that directs the processing gas upward, and a third passage portion that directs the processing gas downward. The processing gas from the third passage portion is blown out from the slit and sprayed downward to the workpiece.

### PRIOR ART DOCUMENTS

### Patent Documents

Patent Document 1: Japanese Patent Laid-Open Publication No. 2012-199487

### SUMMARY

According to one aspect of the present disclosure, a shower head assembly, which is disposed in a film forming apparatus that alternately repeats film formation and etching to form a metal film in a recess formed in a substrate, includes: a first plate having arc-shaped first slits formed in the first plate; and a second plate having arc-shaped second slits formed in the second plate, wherein the second plate is disposed below the first plate to vertically overlap with the first plate, and the second slits are formed at locations such that the second slits do not overlap with the first slits in a plan view.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a configuration of a film forming apparatus according to one embodiment.

FIG. 2 is a flowchart illustrating an example of a film forming method according to one embodiment.

FIG. 3 is a schematic cross-sectional view illustrating a configuration example of a shower head assembly according to a first embodiment.

FIG. 4 is a diagram illustrating an example of Evaluation Result 1 of the shower head assembly according to the first embodiment.

FIG. 5 is a diagram illustrating an example of Evaluation Result 2 of the shower head assembly according to the first embodiment.

FIGS. 6A and 6B are views illustrating a configuration example of a shower head assembly according to a second embodiment and an example of a gas flow path of a second ring, respectively.

FIG. 7 is a diagram illustrating an example of Evaluation Result 3 of the shower head assembly according to the second embodiment.

FIGS. 8A and 8B are views illustrating a configuration example of a shower head assembly according to a modification of the second embodiment and an example of a gas flow path of a second plate, respectively.

FIG. 9 is a diagram illustrating an example of Evaluation Result 4 of the shower head assembly according to the modification of the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to the drawings. In each drawing, the same reference numerals may be given to the same components, and redundant descriptions may be omitted.

In this specification, orientations such as parallel, right angle, orthogonal, horizontal, vertical, up-and-down, left-and-right, and the like may allow for slight deviations that do not compromise effects of the embodiments. A shape of a corner is not limited to a right angle, but may be rounded in an arc shape. Terms such as parallel, right angle, orthogonal, horizontal, vertical, circular, and coincident may include substantially parallel, substantially right angle, substantially orthogonal, substantially horizontal, substantially vertical, substantially circular, and substantially coincident.

### [Film Forming Apparatus]

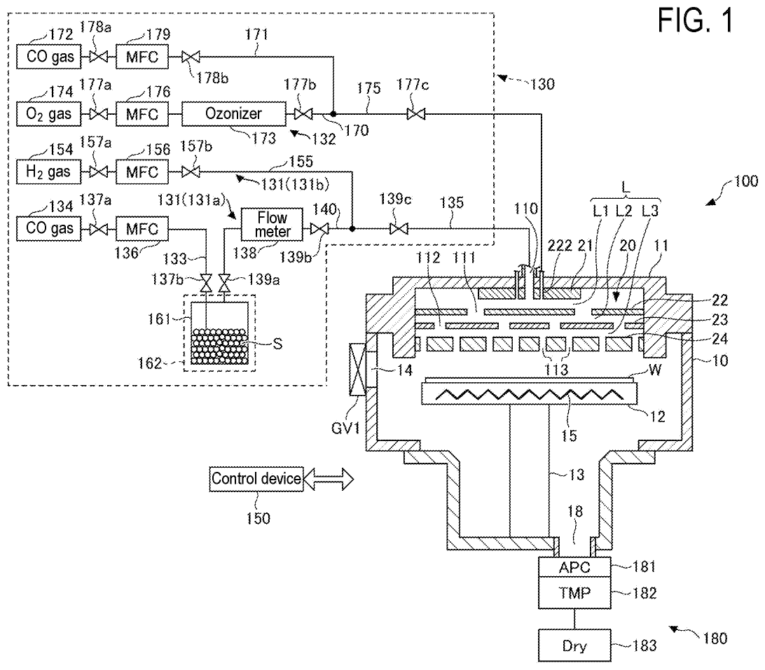

A configuration of a film forming apparatus according to one embodiment will be described with reference to FIG. 1. FIG. 1 is a schematic cross-sectional view illustrating an example of a configuration of a film forming apparatus 100 according to one embodiment. The film forming apparatus 100 includes a processing container 10, and a transfer port 14 for loading and unloading a substrate is formed in the processing container 10. The transfer port 14 is configured to be opened and closed by a gate valve GV1.

A stage 12 configure to support a substrate W horizontally is provided inside the processing container 10, and is supported by a support column 13 from below. The stage 12 includes a heater 15 to heat the substrate W to a preset temperature.

A shower head assembly 20 is disposed on a ceiling of the processing container 10 to face the substrate W placed on the stage 12. The shower head assembly 20 has a gas diffusion space L. The shower head assembly 20 includes a first plate 22, a second plate 23, and a third plate 24 in order from top inside a region surrounded by a lid 11. The gas diffusion space L enclosed between the lid 11 and the third plate 24 has a gas flow path L1, a gas flow path L2, and a gas flow path L3.

The first plate 22 has a disk shape in which arc-shaped first slits 111 are formed. The second plate 23 has a disk shape in which arc-shaped second slits 112 are formed. The third plate 24 has a disk shape in which arc-shaped third slits 113 are formed.

The second plate 23 is disposed below the first plate 22 to overlap with the first plate 22 in a plan view, and the second slits 112 are formed at locations such that the second slits 112 do not overlap with the first slits 111 in a plan view.

The third plate 24 is disposed below the second plate 23 to overlap with the second plate 23 in a plan view, and the third slits 113 are formed at locations such that the third slits 113 do not overlap with both of the first slits 111 and the second slits 112 in a plan view.

Among the first plate 22, the second plate 23, and the third plate 24, the number of slits in a radial direction of a plate increases as the plate is located lower. The second plate 23 has a larger number of slits in the radial direction than the first plate 22. The third plate 24 has a larger number of slits in the radial direction than the second plate 23.

Among the first plate 22, the second plate 23, and the third plate 24, a central axis of a slit in an adjacent upper plate coincides with a center between slits in an adjacent lower plate. For example, a center axis of the first slit 111 in the first plate 22 coincides with a center between the second slits 112 in the second plate 23 located below the first plate 22. Similarly, a center axis of the second slit 112 in the second plate 23 coincides with a center between the third slits 113 in the third plate 24 located below the second plate 23.

The film forming apparatus 100 includes a gas supply 130 configured to supply a gas and a gas exhauster 180 configured to exhaust the gas. The gas supply 130 includes a first supply line 131 configured to supply a gas including a raw material gas of ruthenium and a hydrogen-containing gas to the processing container 10, and a second supply line 132 configured to supply a gas including ozone gas. The first supply line 131 includes a raw material gas supply line 131a configured to supply the gas including the raw material gas of ruthenium and a hydrogen gas supply line 131b configured to supply the hydrogen-containing gas.

The raw material gas supply line 131a includes a carrier gas supply pipe 133 and supply pipes 140 and 135. The carrier gas supply pipe 133 extends from a CO gas source 134 and is connected to a raw material container 161. The supply pipe 133 is provided with a valve 137a, a mass flow controller 136, and a valve 137b in order from a side of the CO gas source 134. CO gas is supplied as a carrier gas from the CO gas source 134 to the raw material container 161 via the supply pipe 133. However, instead of the CO gas, an inert gas such as argon (Ar) gas or nitrogen (N₂) gas may also be used as the carrier gas.

The raw material container 161 accommodates therein a raw material S of ruthenium. In this example, dodecacarbonyltriruthenium (DCR) as the raw material S for ruthenium film is accommodated in the raw material container 161. However, the raw material S for ruthenium film is not limited to DCR, and may be an organic-based raw material. The raw material S inside the raw material container 161 is heated and vaporized by a heater 162.

A gas inlet port 110 is formed in the lid 11 above the first plate 22, which will be described later, and at least the raw material gas (film forming gas) is introduced via the gas inlet port 110. A central axis of the first plate 22 coincides with a central axis of the gas inlet port 110. The raw material container 161 and the gas inlet port 110 of the shower head assembly 20 are connected to each other by the supply pipes 140 and 135. An upper end surface of the raw material container 161 is connected to the supply pipe 140, the supply pipe 140 is connected to the supply pipe 135, and the supply pipe 135 is connected to the gas inlet port 110. The supply pipe 140 is provided with a valve 139a, a flow meter 138, and a valve 139b in order from a side of the raw material container 161. The supply pipe 135 is provided with a valve 139c.

The raw material gas of ruthenium vaporized in the raw material container 161 flows through the supply pipes 140 and 135 using CO gas as a carrier gas, and is supplied to the processing container 10 from the gas inlet port 110. The flow meter 138 detects a flow rate of the raw material gas. With this configuration, a ruthenium film is formed in a recess on a surface of the substrate W by the raw material gas (DCR) supplied from the gas inlet port 110.

When a ruthenium film is formed in a bottom-up manner from a bottom of the recess formed in the substrate W, it is possible to avoid generation of voids or seams to be described later, thereby forming a low-resistance ruthenium film. However, the ruthenium film (hereinafter also referred to as ruthenium pieces) is also formed on a sidewall (side surface) of the recess during a film formation process. When the ruthenium pieces formed on the sidewall is removed by etching, no ruthenium film remains on the side surface of the recess, thereby avoiding generation of voids. Therefore, in the film forming apparatus 100, the ruthenium film is grown in a bottom-up manner from the bottom of the recess by a method of alternately repeating forming the ruthenium film and etching the ruthenium pieces. Thus, it is possible to embed the ruthenium film in the recess in a bottom-up manner, thereby implementing ruthenium wiring and contacts without voids or seams.

In the etching process, O₃ gas and O₂ gas are supplied, as an example of the gas including ozone (O₃) gas, into the processing container 10 from the second supply line 132. The ruthenium pieces formed on the sidewall of the recess are removed by etching using the ozone gas.

The second supply line 132 includes supply pipes 170, 171, and 175. The supply pipe 170 extends from an O₂ gas source 174 and is connected to the supply pipe 175. The supply pipe 171 extends from a CO gas source 172 and is connected to the supply pipe 175. The supply pipe 175 is formed in a vicinity of the gas inlet port 110 and is connected to a first ring 21 having a plurality of first gas discharge ports 222 via which the gas including the O₃ gas is introduced. The first gas discharge ports 222 discharge an etching gas such as O₃ gas and/or a carrier gas such as CO gas. The first gas discharge ports 222 are evenly distributed in ta circumferential direction.

The supply pipe 170 is provided with a valve 177a, a mass flow controller 176, an ozonizer 173, and a valve 177b in order from a side of the O₂ gas source 174. The supply pipe 175 is provided with a valve 177c. A flow rate of oxygen (O₂) gas supplied from the O₂ gas source 174 is controlled by the mass flow controller 176, and is then supplied to the ozonizer 173. The ozonizer 173 discharges the oxygen gas by electrical energy to generate O₃ gas, controls a concentration of the O₃ gas with respect to the O₂ gas, and outputs a gas mixture of the O₃ gas, which has been controlled to have a certain concentration, and the O₂ gas.

The gas mixture of the O₃ gas and the O₂ gas is an example of the gas including the O₃ gas. The gas mixture of the O₃ gas and the O₂ gas passes through the lid 11, which forms a ceiling surface of the processing container 10, via the supply pipe 175, and is supplied to the processing container 10 from the first gas discharge ports 222 formed in the first ring 21. Thus, the ruthenium pieces formed on the sidewall of the recess on the substrate W are etched and removed.

The supply pipe 171 is provided with a valve 178a, a mass flow controller 179, and a valve 178b in order from a side of the CO gas source 172. A flow rate of CO gas supplied from the CO gas source 172 is controlled by the mass flow controller 179.

The first supply line 131 further includes a supply pipe 155 branched from the supply pipe 135. The supply pipe 155 extends from a H₂ gas source 154 and is connected to the supply pipe 135. The supply pipe 155 is provided with a valve 157a, a mass flow controller 156, and a valve 157b in order from a side of the H₂ gas source 154.

A flow rate of hydrogen (H₂) gas supplied from the H₂ gas source 154 is controlled by the mass flow controller 156. The hydrogen gas is an example of the hydrogen-containing gas. The hydrogen gas is supplied to the processing container 10 via the supply pipes 155 and 135. Thus, the ruthenium film is modified (reduced) by the hydrogen-containing gas. In this example, the hydrogen gas, which is a reducing gas, is used as a reaction gas. In addition, eH₂ gas plasma, NH₃ gas, NH₃ plasma, monomethylhydrazine (MMH), hydrazine (N₂H₄), and the like may be used as the reaction gas.

The gas exhauster 180 includes a pressure adjuster (APC) 181 attached to an exhaust port 18, a turbo molecular pump (TMP) 182, and a dry pump (Dry) 183. The dry pump (Dry) 183 roughly empties an interior of the processing container 10 and exhausts a residual gas of the raw material gas of ruthenium. The turbo molecular pump 182 vacuum-draws the interior of the processing container 10 while adjusting an internal pressure of the processing container 10 by the pressure adjuster 181.

The film forming apparatus 100 includes a control device 150 configured to control operations of respective components of the film forming apparatus 100. The control device 150 is configured by, for example, a computer having a CPU and a memory (storage), which are not illustrated, and the memory stores a process recipe, which includes a group of steps (commands) related to a control necessary to perform a film forming method to be described later. The process recipe may be stored in a non-transitory computer-readable storage medium such as a hard disk and installed from the storage medium onto the computer, or may be acquired using a communication means from a network connected to the control device 150.

### [Film Forming Method]

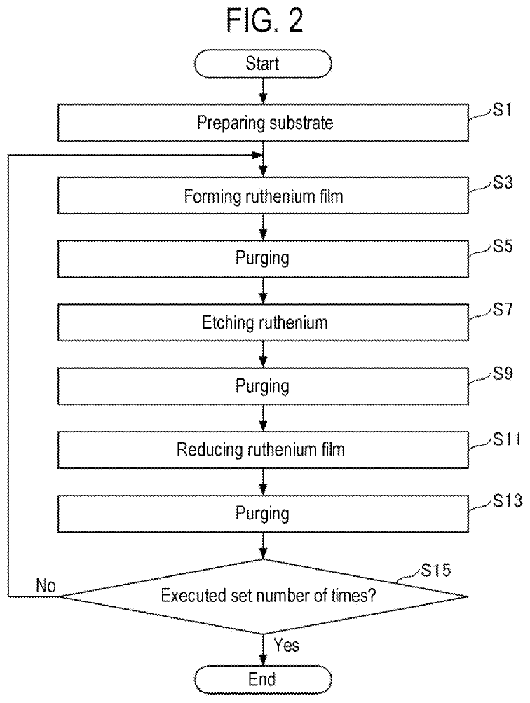

Next, an example of a film forming method according to an embodiment, which is executed by a film forming system 1, will be described with reference to FIG. 2 as well as FIG. 1. FIG. 2 is a flowchart illustrating an example of a film forming method according to one embodiment. The film forming method illustrated in FIG. 2 is controlled by the control device 150 and is executed in the film forming apparatus 100. As for gases used in this film forming method, a film forming gas is DCR gas, an etching gas is a gas mixture of O₃ gas and O₂ gas, a carrier gas is CO gas, and a reducing gas is H₂ gas. These gases are used to embed a ruthenium film in the recess of the substrate W.

When a processing is initiated, in step S1, the control device 150 loads the substrate W into the processing container 10 to place it on the stage 12, heats the substrate W by the heater 15, and evacuates the interior of the processing container 10 by the gas exhauster 180.

Subsequently, in step S3, the control device 150 controls the film forming apparatus 100 to form a ruthenium film in the recess on the substrate W. The ruthenium film is formed in the recess on the substrate W using a vaporized raw material gas of ruthenium under a control with the following process conditions.

In the raw material container 161 illustrated in FIG. 1, DCR as the raw material S of ruthenium is heated by the heater 162. The valves 137a and 137b provided in the carrier gas supply pipe 133 of the first supply line 131 are opened, and the CO gas, which is a carrier gas having a flow rate controlled by the mass flow controller 136, is supplied to the raw material container 161. The raw material of ruthenium is vaporized by heating using the heater 162. At this time, the valves 139a, 139b, and 139c provided in the supply pipes 140 and 135 are open. Thus, the vaporized raw material gas is supplied into the processing container 10, the ruthenium film is formed on the substrate W.

The valve 139c is open when forming the ruthenium film. Thus, the gas including the raw material gas of ruthenium is supplied into the processing container 10 from the gas inlet port 110, and the ruthenium film is formed. At this time, the valve 177c may be open to supply the CO gas as a carrier gas into the processing container 10. In addition, the valve 177c may be closed when forming the ruthenium film according to conditions of a film formation process.

During the formation of the ruthenium film in step S3, the gas exhauster 180 exhausts the gas including the raw material gas of ruthenium inside the processing container 10. After lapse of a predetermined time after starting the process of step S3, the control device 150 closes the valve 139c and stops the supply of the gas including the raw material gas of ruthenium.

Subsequently, in step S5, the gas exhauster 180 vacuum-evacuates the interior of the processing container 10. Along with the vacuum-evacuation, a purge process of supplying an inert gas such as Ar gas or N₂ gas into the processing container 10 and replacing the gas including the raw material gas of ruthenium inside the processing container 10 with the inert gas is performed.

Subsequently, in step S7, ruthenium pieces attached to the sidewall of the recess on the substrate W is etched and removed. During the etching in step S7, the valve 139c is closed. In addition, the valve 177c and the valves 177a and 177b of the second supply line 132 are opened, and the valves 178a and 178b are closed. Thus, the gas mixture of O₃ gas and O₂ gas, which has a predetermined concentration and is output from the ozonizer 173, is supplied into the processing container 10 from the first gas discharge ports 222. Therefore, the gas including the O₃ gas is supplied into the processing container 10 and the substrate W is etched, thereby removing the ruthenium pieces from the sidewall of the recess. In addition, the gas exhauster 180 exhausts the gas including the O₃ gas inside the processing container 10.

Subsequently, in step S9, the gas exhauster 180 vacuum-evacuates the interior of the processing container 10. Along with the vacuum-evacuation, a purge process of supplying an inert gas into the processing container 10 and replacing the gas including the O₃ gas inside the processing container 10 with the inert gas is performed.

Subsequently, in step S11, the valve 157a, valve 157b, and valve 139c of the hydrogen gas supply line 131b are opened. In the hydrogen gas supply line 131b, the hydrogen gas, which is output from the H₂ gas source 154 and has a flow rate controlled by the mass flow controller 156, is supplied into the processing container 10. A ruthenium oxide layer formed on a surface layer of the ruthenium film may be reduced with the hydrogen gas, thereby being modified into a ruthenium film. The gas exhauster 180 exhausts the hydrogen gas inside the processing container 10.

Subsequently, in step S13, a purge process of vacuum-evacuating the interior of the processing container 10 by the gas exhauster 180 and supplying an inert gas into the processing container 10 to replace the hydrogen gas inside the processing container 10 with the inert gas is performed.

Subsequently, the control device 150 determines whether or not a ruthenium embedding process (steps S3 to S13) has been performed a set number of times. When the control device 150 determines that the ruthenium embedding process has not been performed the set number of times, the control device 150 returns to step S3 to execute steps S3 to S13. Accordingly, the film formation and etching are repeated the set number of times. When the control device 150 determines that the ruthenium film formation process has been performed the set number of times, the control device 150 unloads the substrate W.

As described above, in the film forming method according to one embodiment, after forming the ruthenium film, the gas including O₃ gas is supplied into the same film forming apparatus 100 to perform an etching process. Thus, the ruthenium film formation process and the etching process are repeated, it is possible to embed the ruthenium film in the recess of the substrate W in a bottom-up manner without generating voids. In addition, in addition to the ruthenium film formation and etching, a hydrogen-containing gas is supplied into the same film forming apparatus 100 to reduce a ruthenium oxide film, thereby forming a ruthenium film with even lower resistance.

The arc-shaped first slits 111, second slits 112, and third slits 113 in the respective of the first plate 22, the second plate 23, and the third plate 24 of the shower head assembly 20 are disposed in a staggered manner such that they do not overlap with one another in a plan view. In other words, the concentric first slits 111, second slits 112, and third slits 113 are disposed in a staggered manner so as not to overlap with one another in the radial direction. Thus, the gas flow path L1, the gas flow path L2, and the gas flow path L3 are formed such that a gas diffusion path expands from top to bottom in a tournament manner. Therefore, the gas is diffused via the gas flow paths L1 to L3 and the first slits 111, the second slits 112, and the third slits 113, and it is possible to uniformly discharge the gas from the third slits 113 into a processing space above the substrate W. Accordingly, it is possible to improve in-plane uniformity in the film formation process and the etching process.

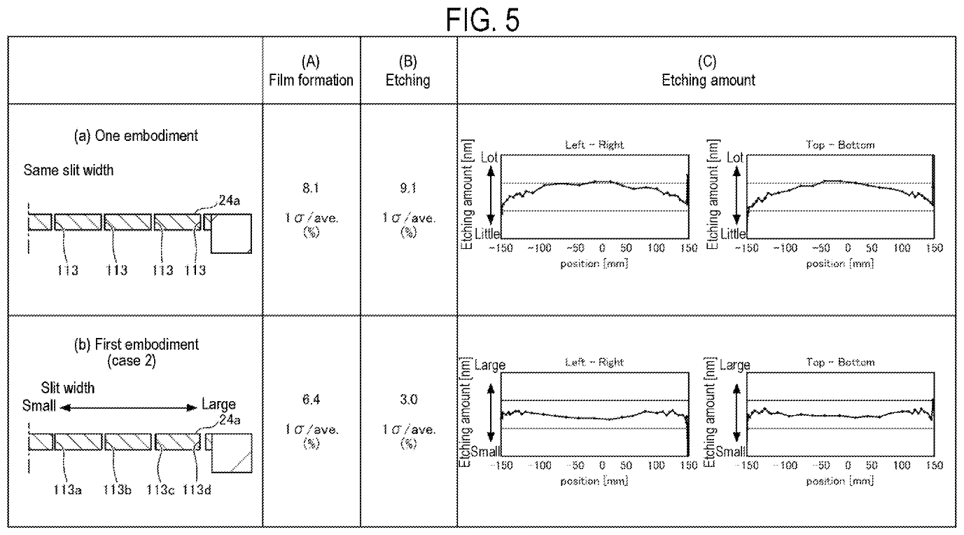

However, in the film forming apparatus according to one embodiment (see FIG. 1), it has been confirmed that there is a tendency in the etching process that an etching amount is greater at a center than at an outer periphery (see (a) of FIG. 5). Therefore, it is necessary to improve in-plane uniformity of the etching amount in the etching process while maintaining in-plane uniformity of a film thickness of the ruthenium film in the film formation process.

Therefore, a configuration example of the shower head assembly is proposed, which may improve in-plane uniformity of an etching amount by changing a flow of an etching gas while maintaining in-plane uniformity of a film thickness of the ruthenium film in the film formation process without changing a flow of a film forming gas. In the following, a configuration example of the shower head assembly will be described in the order of a first embodiment, a second embodiment, and a modification of the second embodiment.

### First Embodiment

### [Configuration of Shower Head Assembly]

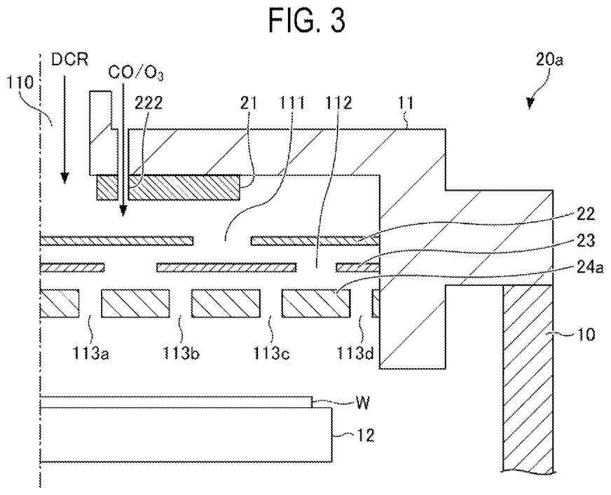

A configuration example of a shower head assembly 20a according to a first embodiment will be described with reference to FIG. 3. FIG. 3 is a schematic cross-sectional view illustrating a configuration example of the shower head assembly 20a according to the first embodiment.

Radial widths of the third slits 113 formed in the third plate 24 of the shower head assembly 20 according to the one embodiment illustrated in FIG. 1 are all the same. In contrast, in a third plate 24a of the shower head assembly 20a according to the first embodiment, radial widths of the third slits 113 are different from one another. The other configurations of the shower head assembly 20a are the same as those of the shower head assembly 20. Thus, in the first embodiment, a configuration of the third plate 24a will be described, and description of the other configurations of the shower head assembly 20a will be omitted.

As illustrated in FIG. 3, in the third plate 24a according to the first embodiment, a plurality of third slits 113a, 113b, 113c, and 113d is formed in a radial direction. Slit widths of the plurality of third slits 113a, 113b, 113c, and 113d in the radial direction increase as the third slit is located closer to the outer periphery. In other words, the slit width of the outermost third slit 113d in the radial direction is larger than the slit width of the innermost third slit 113a. For example, the slit widths of the plurality of third slits 113a, 113b, 113c, and 113d in the radial direction increase as the third slit 113 is located closer to the outer periphery.

In addition, as for the slit widths of adjacent third slits 113 in the radial direction, the slit width of the third slit 113 closer to the outer periphery is equal to or larger than that of the third slit 113 closer to the inner periphery.

### Evaluation Result 1

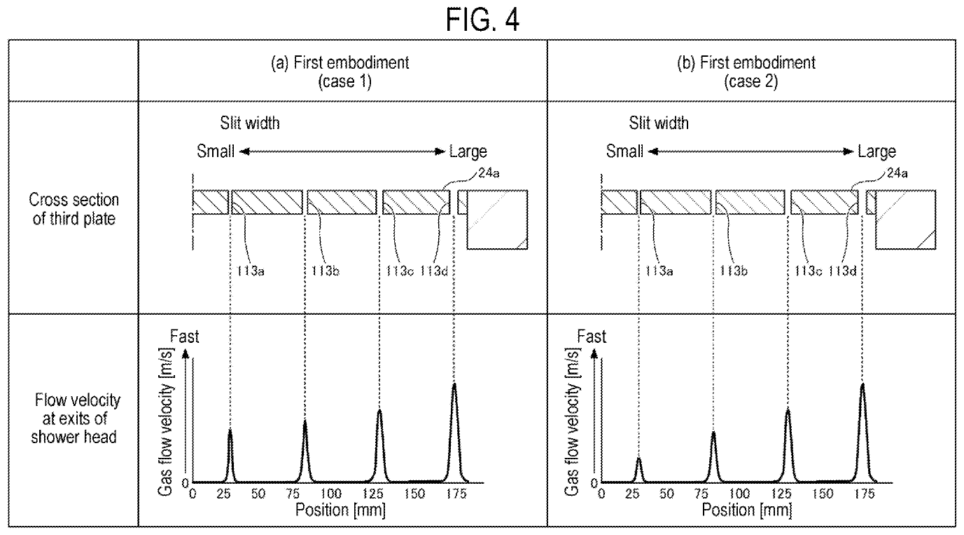

Evaluation Result 1 of the shower head assembly 20a according to the first embodiment will be described with reference to FIG. 4. FIG. 4 is a diagram illustrating an example of Evaluation Result 1 of the shower head assembly 20a according to the first embodiment.

In a simulation for obtaining Evaluation Result 1, an internal pressure of the processing container 10 was set to 100 mmTorr (13.33 Pa), a flow rate of the gas mixture of O₃ gas and O₂ gas was set to 1000 sccm, and ae concentration of O₃ gas was set to 300 g/m³.

In (a) of FIG. 4 for the first embodiment (Case 1), the slit widths of the third slits 113a, 113b, 113c, and 113d were set to be larger toward the outer periphery. Similarly, in (b) of FIG. 4 for the first embodiment (Case 2), the slit widths of the third slits 113a, 113b, 113c, and 113d were set to be larger toward the outer periphery. In addition, the slit width of the third slit 113a in (a) of FIG. 4 was set to be larger than the slit width of the third slit 113a in (b) of FIG. 4. The slit width of the third slit 113b in (a) of FIG. 4 was set to be larger than the slit width of the third slit 113b in (b) of FIG. 4. The slit widths of the third slits 113c and 113d in (a) of FIG. 4 were set to be the same as the slit widths of the third slits 113c and 113d in (b) of FIG. 4, respectively.

In the graphs of (a) and (b) of FIG. 4, the horizontal axis represents an exit position of the shower head assembly 20a, i.e., exit positions of the third slits 113a to 113d in the third plate 24a, and the vertical axis represents a flow velocity of a gas in a longitudinal direction (vertical direction) at each exit position. In both of Case 1 and Case 2, since the slit widths of the third slits 113 increase toward the outer periphery, the flow velocity of the gas at the exits of the third slits 113 increases toward the outer periphery. That is, in the shower head assembly 20a according to the first embodiment, the flow velocity of the gas at the exits increases toward the outer periphery.

### Evaluation Result 2

Evaluation Result 2 of the shower head assembly 20a according to the first embodiment will be described with reference to FIG. 5. FIG. 5 is a diagram illustrating an example of Evaluation Result 2 of the shower head assembly 20a according to the first embodiment.

In a simulation for obtaining Evaluation Result 2, the film forming method illustrated in FIG. 2 was performed. A film forming gas was DCR gas, an etching gas was a gas mixture of O₃ gas and O₂ gas, a carrier gas was CO gas, and H₂ gas was used as a hydrogen-containing gas.

In the shower head assembly 20 (see FIG. 1) according to the one embodiment illustrated in (a) of FIG. 5, the radial widths of the third slits 113 in the third plate 24 were set to be all the same. In the shower head assembly 20a (see FIG. 3) according to the first embodiment (Case 2) illustrated in (b) of FIG. 5, the slit widths of the third slits 113a to 113d in the third plate 24 were set to increase toward the outer periphery.

Thus, in the shower head assembly 20a according to the first embodiment (Case 2) in (b) of FIG. 5, an etching gas flows more readily toward the outer periphery, compared to the shower head assembly 20 according to the one embodiment in (a) of FIG. 5.

As a result, as illustrated in the results of the etching process in (B) of FIG. 5, in the shower head assembly 20a of the first embodiment, a degree of variation (1 σ/ave (%)) in the radial direction in the etching amount on the substrate W was “3.0.” On the other hand, a degree of variation in the shower head assembly 20 according to the one embodiment was “9.1.” Accordingly, the shower head assembly 20a of the first embodiment exhibited higher in-plane uniformity of the etching amount, compared to the shower head assembly 20 according to the one embodiment.

In addition, in the graph of the etching amount in (C) of FIG. 5, the horizontal axis represents a radial position of the substrate W, which is a 300 mm wafer, and the vertical axis represents the etching amount. As illustrated in the graph, the etching amount in the radial direction of the substrate W for the shower head assembly 20 exhibited less variation and improved in-plane uniformity between the center and the outer periphery, compared to the shower head assembly 20.

In addition, as illustrated in the results of the film formation process in (A) of FIG. 5, in the shower head assembly 20a of the first embodiment, a degree of variation (1 σ/ave (%)) in the radial direction in the film thickness of the substrate W when forming the film was “6.4.” A degree of variation in the shower head assembly 20 according to the one embodiment was “8.1.” In the shower head assembly 20a of the first embodiment, the in-plane uniformity of the film thickness in the film formation process was substantially unchanged compared to the shower head assembly 20 according to the one embodiment.

From the above Evaluation Results 1 and 2, in the first embodiment, the widths of the third slits 113a to 113d in the lowermost third plate 24a among the three plates of the shower head assembly 20a increase toward the outer periphery. Thus, it is possible to cause the gas including O₃ gas as an etching gas to flow more easily toward the outer periphery, and thus, it is possible to further improve the in-plane uniformity of the etching amount in the etching process while maintaining the in-plane uniformity of the film thickness in the film formation process.

In particular, it is easy to maintain the in-plane uniformity of the film thickness when performing a film formation process within a low temperature range (e.g., 100 degrees C.). In contrast, in a film formation process within a high temperature range (e.g., 250 degrees C.), there are cases where a further adjustment of the widths of the third slits is required to maintain the in-plane uniformity of the film thickness. Therefore, in a second embodiment, a configuration of a shower head assembly 20b that is capable of improving the in-plane uniformity of the etching amount while maintaining the in-plane uniformity of the film thickness regardless of a temperature range in the film formation process will be described.

### Second Embodiment

### [Configuration of Shower Head Assembly]

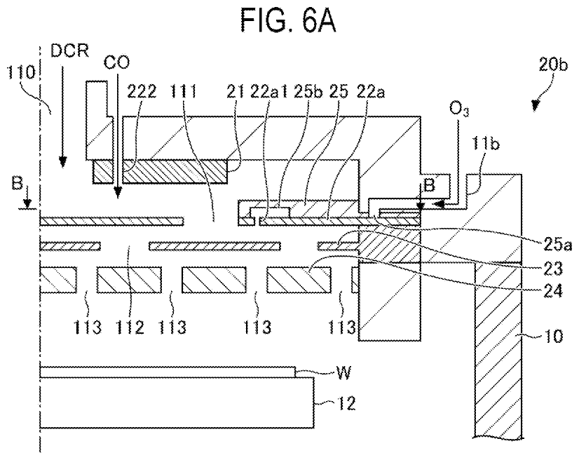

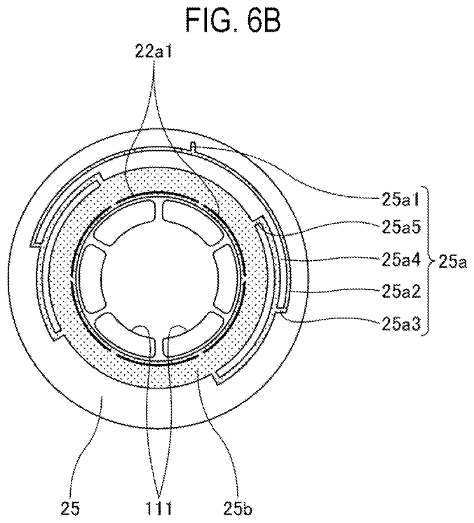

Hereinafter, a configuration example of the shower head assembly 20b according to the second embodiment will be described with reference to FIGS. 6A and 6B. FIG. 6A is a schematic cross-sectional view illustrating a configuration example of the shower head assembly 20b according to the second embodiment. FIG. 6B is a view illustrating an example of a gas flow path of a second ring 25 included in the shower head assembly 20b.

The shower head assembly 20 according to the one embodiment illustrated in FIG. 1 includes the first plate 22, the second plate 23, and the third plate 24. In contrast, the shower head assembly 20b according to the second embodiment includes a first plate 22a, a second plate 23, a third plate 24, and a second ring 25. Configurations of the second plate 23 and the third plate 24 is the same as those of the second plate 23 and the third plate 24 included in the shower head assembly 20. The first plate 22a differs from the first plate 22 included in the shower head assembly 20. In addition, the shower head assembly 20b has differences in that the second ring 25 is provided and a gas flow path is formed in the lid 11. Therefore, in the second embodiment, configurations of the lid 11, the first plate 22a, and the second ring 25 will be described, and description of the other configurations of the shower head assembly 20b will be omitted.

The lid 11 has a gas flow path 11b formed in the vertical direction from an outer peripheral upper surface of the lid 11. The second ring 25 has a ring shape and is disposed on an outer peripheral upper surface of the first plate 22a at a location outward the outermost first slit 111. The second ring 25 has an inner peripheral portion thicker than an outer peripheral portion thereof. A first gas flow path 25a configured to introduce an etching gas is formed in the outer peripheral portion of the second ring 25, and a first buffer region 25b configured to temporarily storing the etching gas is formed in the inner peripheral portion.

The gas flow path 11b is bent horizontally inward in an interior of the lid 11, and in communication with the first gas flow path 25a of the second ring 25 on a lower surface of the lid 11. The first buffer region 25b is in communication with a plurality of second gas discharge ports 22a1, which is formed in the first plate 22a and disposed evenly in a circumferential direction of the first plate 22a.

A cross-sectional view of the second ring 25 taken horizontally along B-B plane is illustrated in FIG. 6B. The ring-shaped first buffer region 25b is formed in the second ring 25. An inner periphery of the first buffer region 25b substantially coincides with an outer periphery of the arc-shaped first slits 111 in the first plate 22a. The first gas flow path 25a, which is branched in a tournament manner, is formed outward the first buffer region 25b.

The first gas flow path 25a is branched into two gas flow paths 25a2 extending in a circumferential direction from a gas entrance 25al, and at a leading end of each of the gas flow paths 25a2, is further branched into two gas flow paths 25a4 extending in the circumferential direction via a gas flow path 25a3 extending in a radial direction. A gas is supplied to the first buffer region 25b from four gas flow paths 25a5 connected to leading ends of the gas flow paths 25a4. Connection ports (exits of the gas flow paths 25a5) of the first gas flow path 25a to the first buffer region 25b are disposed evenly in a circumferential direction of the ring-shaped first buffer region 25b.

As described above, the first gas flow path 25a is branched into four branches from the gas entrance 25al and connected to the first buffer region 25b. However, the number of branches of the first gas flow path 25a is not limited to four and may be any number. The respective branches of the first gas flow path 25a have the same length.

Accordingly, it is possible to evenly supply the gas from the first gas flow path 25a to the first buffer region 25b. The gas temporarily stored in the first buffer region 25b is supplied toward the second plate 23 from the plurality of slit-shaped second gas discharge ports 22al formed in the first plate 22a.

Returning to FIG. 6A, the plurality of second gas discharge ports 22al is disposed closer to the outer periphery than the plurality of first gas discharge ports 222. The plurality of second gas discharge ports 22al supplies the gas including O₃ gas, i.e., an etching gas. The plurality of first gas discharge ports 222 may supply CO gas during the film formation process.

Accordingly, it is possible to supply an etching gas including O₃ gas from a side of the outer periphery of the lid 11 into a space on a side of the outer periphery inside the processing container 10 via the interior of the second ring 25 without changing a flow of the film forming gas in the ruthenium film formation process. Thus, it is possible to further improve the in-plane uniformity of etching the substrate W without affecting the ruthenium film formation.

The plurality of first gas discharge ports 222 may be configured to supply the gas including O₃ gas, in addition to the CO gas. For example, the gas supplied from the plurality of first gas discharge ports 222 may be switched between the CO gas and the O₃ gas according to process conditions. When a flow rate of the O₃ gas supplied from the side of the outer periphery of the lid 11 is insufficient, O₃ gas may be supplied from the plurality of first gas discharge ports 222 provided at the center. In addition, the supply of the gas including O₃ gas may be switched between the plurality of first gas discharge ports 222 and the plurality of second gas discharge ports 22al during the etching process.

DCR gas and CO gas as a carrier gas are supplied from the gas inlet port 110. In addition, in the shower head assembly 20b of the second embodiment, the second plate 23 and the third plate 24 have the same configurations as the second plate 23 and the third plate 24 of the shower head assembly 20 (see FIG. 1) according to the one embodiment.

### Evaluation Result 3

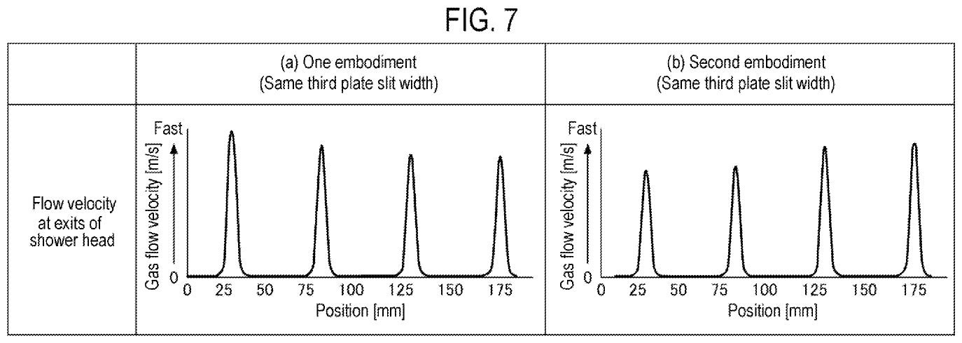

Evaluation Result 3 of the shower head assembly 20b according to the second embodiment will be described with reference to FIG. 7. FIG. 7 is a diagram illustrating an example of Evaluation Result 3 of the shower head assembly 20b according to the second embodiment.

In a simulation for obtaining Evaluation Result 3, the internal pressure of the processing container 10 was set to 100 mmTorr (13.33 Pa), the flow rate of the gas mixture of O₃ gas and O₂ gas was set to 1000 sccm, and the concentration of the O₃ gas was set to 300 g/m³.

In the graphs of (a) and (b) of FIG. 7, the horizontal axis represents exit positions of the shower head assemblies 20 and 20b, i.e., exit positions of the third slits 113 in the third plate 24, and the vertical axis represents a flow velocity of a gas in the longitudinal direction (vertical direction) at each exit position. The slit widths of the third slits 113 in the third plate 24 of the shower head assemblies 20 and 20b are the same.

In (a) of FIG. 7 for the shower head assembly 20 according to the one embodiment, the flow velocity of the gas at the exits of the third slits 113 is slower at a side of the outer periphery than at a side of the center. In (b) of FIG. 7 for the shower head assembly 20b according to the second embodiment, the flow velocity of the gas at the exits of the third slits 113 is faster at a side of the outer periphery than at a side of the center.

In the shower head assembly 20b according to the second embodiment, the gas flow path 11b is provided in an outer peripheral portion of the lid 11. The etching gas including O₃ gas is supplied from the gas flow path 11b, passes through the first gas flow path 25a and the first buffer region 25b of the second ring 25, and is then supplied from the plurality of second gas discharge ports 22al in the first plate 22a to a side of the outer periphery of the processing container 10. By changing the flow of the etching gas as described above to make more amount of the etching gas flow at the side of the outer periphery, it is possible to make the flow velocity of the gas at the exits of the third slits 113 be faster at the side of the outer periphery than at the side of the center.

### Modification of Second Embodiment

### [Configuration of Shower Head Assembly]

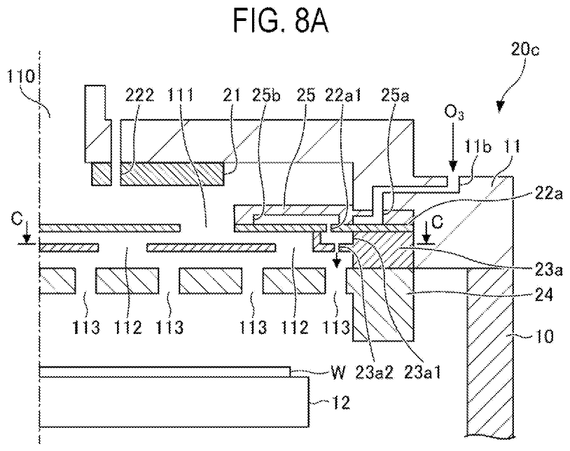

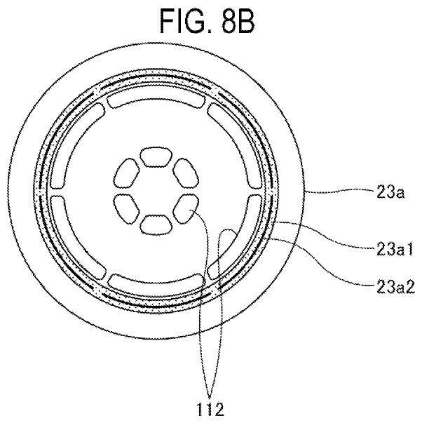

Hereinafter, a configuration example of a shower head assembly 20c according to a modification of the second embodiment will be described with reference to FIGS. 8A and 8B. FIG. 8A is a schematic cross-sectional view illustrating a configuration example of the shower head assembly 20c according to a modification of the second embodiment. FIG. 8B is a view illustrating an example of a gas flow path of a second plate 23a included in the shower head assembly 20c.

The shower head assembly 20b according to the second embodiment includes the first plate 22a, the second plate 23, the third plate 24, and the second ring 25. On the other hand, the shower head assembly 20c according to the modification of the second embodiment includes the first plate 22a, a second plate 23a, the third plate 24, and the second ring 25. Accordingly, in the modification of the second embodiment, a configuration of the second plate 23a, which is different from that of the second embodiment, will be described, and description of the other configurations of the shower head assembly 20c will be omitted.

The second plate 23a includes a ring-shaped second buffer region 23al configured to temporarily store an etching gas, and a plurality of third gas discharge ports 23a2 which is evenly distributed and in communication with the second buffer region 23al at locations below the second buffer region 23al.

The plurality of third gas discharge ports 23a2 is disposed closer to the outer periphery than the plurality of second gas discharge ports 22al, and introduces the etching gas including O₃ gas to the side of the outer periphery inside the processing container 10. The plurality of third gas discharge ports 23a2 flows the etching gas toward the third plate 24.

A cross-sectional view of the second plate 23a taken horizontally along C-C plane is illustrated in FIG. 8B. The ring-shaped second buffer region 23al is formed in the second plate 23a. An inner periphery of the second buffer region 23al substantially coincides with an outer periphery of the second slits 112 in the second plate 23a. The second buffer region 23al is in communication with the plurality of third gas discharge ports 23a2 provided in the circumferential direction. The third gas discharge ports 23a2 are formed in an arc shape and are evenly arranged in the circumferential direction.

In the shower head assembly 20c according to the modification of the second embodiment, the gas flow path 11b is provided in an outer peripheral portion of the lid 11. O₃ gas) flows from the gas flow path 11b to the plurality of second gas discharge ports 22al in the first plate 22a via the first gas flow path 25a and the first buffer region 25b of the second ring 25.

Further, the gas including O₃ gas is temporarily stored in the second buffer region 23al, and is supplied toward the third plate 24 from the plurality of third gas discharge ports 23a2. Thus, it is possible to supply the etching gas to a location in the processing container 10 closer to the outer periphery of the processing container 10. As described above, by changing the flow of the etching gas such that a more amount of the etching gas flows at the side of the outer periphery, it is possible to make the flow velocity of the gas at the exits of the third slits 113 be faster at the side of the outer periphery than at the side of the center.

### Evaluation Result 4

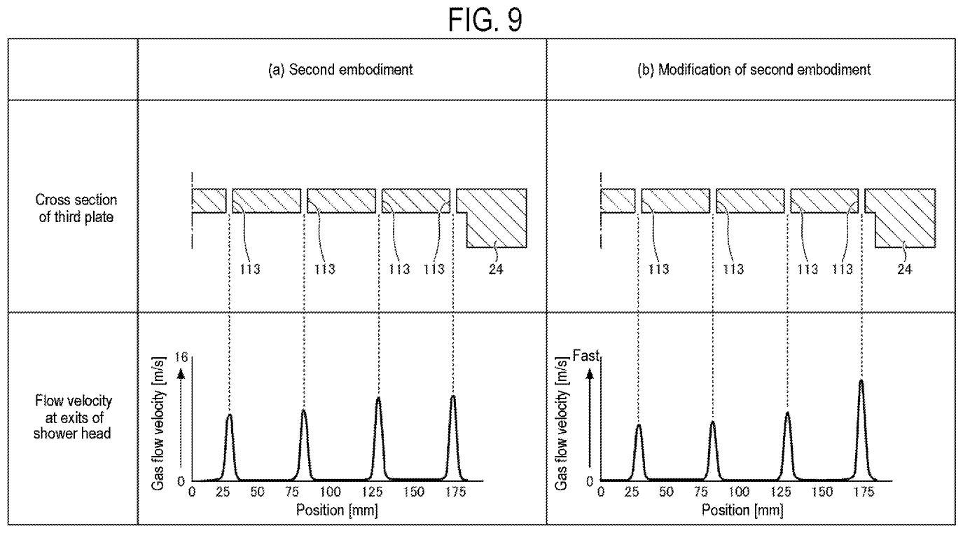

Evaluation Result 4 of the shower head assembly 20c according to the modification of the second embodiment will be described with reference to FIG. 9. FIG. 9 is a diagram illustrating an example of Evaluation Result 4 of the shower head assembly 20c according to the modification of the second embodiment.

In a simulation for obtaining Evaluation Result 4, the internal pressure of the processing container 10 was set to 100 mmTorr (13.33 Pa), the flow rate of the gas mixture of O₃ gas and O₂ gas was set to 1000 sccm, and the concentration of the O₃ gas was set to 300 g/m³.

In the graphs of (a) and (b) of FIG. 9, the horizontal axis represents exit positions of the shower head assembly 20c, i.e., the exit positions of the plurality of third slits 113 in the third plate 24, and the vertical axis represents a flow velocity of a gas in the longitudinal direction (vertical direction) at each exit position. The radial slit widths of the third slits 113 in the third plate 24 are all the same.

A result when using the shower head assembly 20b according to the second embodiment is illustrated in (a) of FIG. 9, and a result when using the shower head assembly 20c according to the modification of the second embodiment is illustrated in (b) of FIG. 9. In both cases, the flow velocity of the gas at the exits becomes faster at the side of the outer periphery than at the side of the center. In addition, in the shower head assembly 20c according to the modification of the second embodiment, the flow velocity of the gas discharged from the outermost third slit 113 becomes significantly faster compared to the shower head assembly 20b according to the second embodiment.

As described above, according to the shower head assembly and film forming apparatus of each embodiment and the modification thereof, the arc-shaped first slits 111 are provided in the first plate 22. The arc-shaped second slits 112 and the arc-shaped third slits 113 are provided in the second plate 23 and the third plate 24, respectively, such that the first slits 111, the second slits 112, and the third slits 113 do not overlap with one another in a plan view. Thus, it is possible to cause a gas to flow downward sequentially from the first plate 22 to the third slits 113 in a tournament manner, and to evenly supply the gas from the center to the outer periphery of the processing space. Accordingly, in the film forming apparatus that alternately repeats the film formation process and the etching process, it is possible to achieve the in-plane uniformity of a substrate processing for both of the film formation and the etching.

In addition, in the shower head assembly 20c according to the modification of the second embodiment, an etching gas flow path is provided in the lid 11, the second ring 25, the first plate 22a, and the second plate 23a. However, the etching gas flow path is not necessarily limited to this. For example, without providing the second ring 25, an etching gas flow path may be formed in the lid 11, the first plate 22a, and the second plate 23a.

The shower head assembly and the film forming apparatus according to the embodiments disclosed herein should be considered to be exemplary and not limitative in all respects. The embodiments may be modified and improved in various forms without departing from the scope of the appended claims and gist thereof. The items described in the above multiple embodiments may also adopt other configurations within a range that is not contradictory, and may also be combined within a range that is not contradictory.

In the embodiments and modification, the shower head assembly includes the first plate 22, the second plate 23, and the third plate 24 that are disposed to overlap with one another vertically. However, the present disclosure is not necessarily limited to this, as along as a plurality of plates overlaps with one another vertically. For example, the shower head assembly may include the first plate 22 having the arc-shaped first slits 111 formed therein and the second plate 23 having the arc-shaped second slits 112 formed therein, without including the third plate 24. In this case, the second plate 23 is disposed below the first plate 22 to vertically overlap with the first plate 22, and the second slits 112 are formed at locations such that the second slits 112 do not overlap with locations of the first slits 111 in a plan view.

In the embodiments and modification, a ruthenium film is formed in the film formation process. However, the film formed in the recess of the substrate is not limited to the ruthenium film, and may be a film made of metal other than ruthenium. A film forming gas is selected according to the metal film to be formed.

According to the present disclosure, in a film forming apparatus that alternately repeats film formation and etching, it is possible to achieve in-plane uniformity of a substrate processing for both of the film formation and the etching.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A shower head assembly disposed in a film forming apparatus that alternately repeats film formation and etching to form a metal film in a recess formed in a substrate, the shower head assembly comprising:
a first plate having arc-shaped first slits formed in the first plate; and
a second plate having arc-shaped second slits formed in the second plate,
wherein the second plate is disposed below the first plate to vertically overlap with the first plate, and the second slits are formed at locations such that the second slits do not overlap with the first slits in a plan view.

2. The shower head assembly of claim 1, further comprising a third plate having arc-shaped third slits,
wherein the third plate is disposed below the second plate to vertically overlap with the second plate, and the third slits are formed at locations such that the third slits do not overlap with both of the first slits and the second slits in a plan view.

3. The shower head assembly of claim 2, further comprising:
a gas inlet port formed above the first plate and configured to introduce at least a film forming gas; and
a first ring formed in a vicinity of the gas inlet port and configured to introduce at least an etching gas or a carrier gas, the first ring having a plurality of first gas discharge ports,
wherein a central axis of the first plate coincides with a central axis of the gas inlet port.

4. The shower head assembly of claim 3, further comprising a second ring disposed on an outer peripheral portion of the first plate and having a first gas flow path configured to introduce the etching gas,
wherein the first plate has a plurality of second gas discharge ports.

5. The shower head assembly of claim 4, wherein the second ring has a ring-shaped first buffer region configured to temporarily store a gas, and
wherein the first gas flow path is branched a plurality of times and connected to the first buffer region, and branches of the first gas flow path have a same length.

6. The shower head assembly of claim 5, wherein the etching gas is supplied toward the second plate via the first gas flow path, the first buffer region, and the plurality of second gas discharge ports.

7. The shower head assembly of claim 6, wherein the third plate has a plurality of third slits formed in a radial direction, and
wherein among the plurality of third slits, a radially outermost slit has a slit width larger than that of a radially innermost slit.

8. The shower head assembly of claim 7, wherein among the plurality of adjacent third slits, a radially outward slit has a slit width equal to or larger than that of a radially inward slit.

9. The shower head assembly of claim 4, wherein the second plate has a plurality of third gas discharge ports, which is disposed closer to an outer periphery of the shower head assembly than the plurality of second gas discharge ports and configured to introduce the etching gas.

10. The shower head assembly of claim 9, wherein the second plate has a ring-shaped second buffer region configured to temporarily store a gas and the plurality of third gas discharge ports, and
wherein the etching gas is supplied toward the third plate via the plurality of third gas discharge ports.

11. The shower head assembly of claim 10, wherein the plurality of first gas discharge ports, the plurality of second gas discharge ports, and the plurality of third gas discharge ports are evenly disposed in a circumferential direction, respectively.

12. The shower head assembly of claim 4, wherein the plurality of second gas discharge ports is disposed closer to an outer periphery of the shower head assembly than the plurality of first gas discharge ports.

13. The shower head assembly of claim 4, wherein the etching gas flows toward the second plate via the plurality of second gas discharge ports.

14. The shower head assembly of claim 3, wherein the film forming gas is dodecacarbonyltriruthenium (DCR) gas, the etching gas is a gas mixture of O₃ gas and O₂ gas, and the carrier gas is CO gas.

15. The shower head assembly of claim 2, wherein among the first plate, the second plate, and the third plate, the number of slits in a radial direction of a plate increases as the plate is located at a lower position.

16. The shower head assembly of claim 2, wherein among the first plate, the second plate, and the third plate, a central axis of a slit in an adjacent upper plate coincides with a center between slits in an adjacent lower plate.

17. The shower head assembly of claim 2, wherein the third plate has a plurality of third slits formed in a radial direction, and
wherein among the plurality of third slits, a radially outermost slit has a slit width larger than that of a radially innermost slit.

18. A film forming apparatus comprising:
a shower head assembly; and
a control device that performs control to alternately repeat film formation and etching to form a metal film in a recess formed in a substrate,
wherein the shower head assembly comprises:
a first plate having arc-shaped first slits formed in the first plate; and
a second plate having arc-shaped second slits formed in the second plate,
wherein the second plate is disposed below the first plate to vertically overlap with the first plate, and the second slits are formed at locations such that the second slits do not overlap with the first slits in a plan view.
